(19) United States
(12) Patent Application Publication
(10) Pub. No.: US 2020/0052637 A1
(43) Pub. Date: Feb. 13, 2020

(54) SYSTEM AND METHOD FOR CONTROLLING MOTOR PARAMETERS

(71) Applicant: AAC Technologies Pte. Ltd., Singapore city (SG)

(72) Inventors: Zheng Xiang, Shenzhen (CN); Xiang Lu, Shenzhen (CN); Hanlin Deng, Shenzhen (CN); Liang Jiang, Shenzhen (CN)

(21) Appl. No.: 16/527,058

(22) Filed: Jul. 31, 2019

(30) Foreign Application Priority Data
Aug. 13, 2018 (CN) 201810918771.7

(51) Int. Cl. H02P 25/034; H03M 1/68; G06F 17/11; G01L 1/12

(52) U.S. Cl. CPC H02P 25/034; G01L 1/125; G06F 17/11; H03M 1/68

(57) ABSTRACT

The present disclosure provides a system and a method for controlling motor parameters. The system includes a feedforward processing module performing a linear processing on a control signal according to parameters; a control object module including a DAC digital to analog converter, an amplifying circuit and an ADC analog to digital converter, a control signal processed by the feedforward processing module passing through the DAC digital to analog converter, and amplified by the amplifier circuit, and passing through the ADC analog to digital converter to obtain a voltage vcm[n] and a current icm[n] across the motor; a system identification module including an LMS adaptive filter, a Least mean square filtering performed on an error signal err[n] between a measurement current icm[n] and a prediction current icp[n], results of iteration feed back to the feedforward processing module, and the feedback results applied to the next data acquisitions and parameters calculations.

### TECHNICAL FIELD

The present disclosure relates to microelectromechanical field, more particularly to a system and a method for controlling motor parameters.

### DESCRIPTION OF RELATED ART

As Linear Resonator Actuators (LRA) become more and more popular in the field of smart phones and tablet computers, etc., how to effectively control motor vibrations becomes very important. In traditional control method, motor excitation signals are controlled by presetting motor parameters, and it's commonly known as open loop control technology. The technology is simple to implement and does not require complicated control theories, but it cannot adaptively adjust according to differences of motor batches and individuals, meanwhile, cannot effectively track parameters variation caused by the change of motor temperature and attitude, and so on.

Therefore, it is necessary to provide a new system and method for controlling motor parameters to solve the above problems.

### BRIEF DESCRIPTION OF THE DRAWINGS

FIG. 1 is a schematic view of a system for controlling motor parameters according to the present disclosure.

### DETAILED DESCRIPTION OF THE EXEMPLARY EMBODIMENT

Hereafter, the present disclosure will be further described with reference to the accompanying drawings and embodiment.

A system for controlling motor parameters of the present disclosure is applied to linear motors equipped in smart phones or tablet computers, which can dynamically track the motor parameters by simply detecting feedback signal.

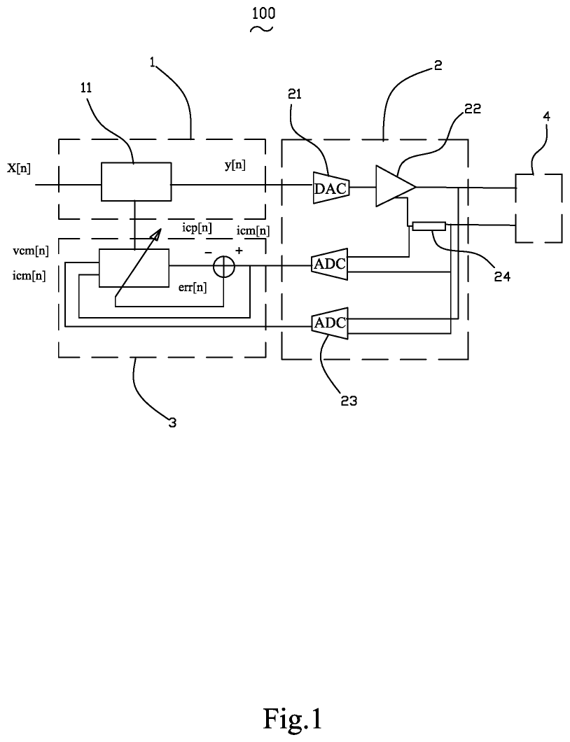

As shown in FIG. 1, the system for controlling motor parameters 100 of the present disclosure comprises a feedforward processing module 1, a control object module 2 and a system identification module 3.

The feedforward processing module 1 has a linear processing unit 11. The feedforward processing unit 11 preforms a linear processing on a control signal according to parameters. Specifically, the linear processing comprises filtering and equalization processing methods, etc., so that the control signal x[n] is processed by the module to obtain y[n].

The control object module 2 comprises a DAC digital to analog converter 21, an amplifying circuit 22 and at least one ADC analog to digital converter 23. The control signal processed by the feedforward processing module 1 passes through the DAC digital to analog converter 21, and then is amplified by the amplifier circuit 22, and then passes through the ADC analog to digital converter 23 to obtain a voltage vcm[n] and a current icm[n] across the motor 4, wherein the current is obtained via a high sensitive resistance 24 having a small resistance value, the resistance 24 is connected with the motor 4 in series.

The system identification module 3 comprises a LMS (Least mean square) adaptive filter. A Least mean square filtering is performed on an error signal err[n] between a measurement current icm[n] and a prediction current icp[n] in the LMS adaptive filter, and the results of iteration are fed back to the feedforward processing module 1, and the feedback results are applied to the next data acquisitions and parameters calculations.

Specially, the present disclosure further provides a method using the above-mentioned system for controlling motor parameters. The method disclosed in the present disclosure mainly comprises the following steps:

step S1: a model for parameters of a vibration motor is modeled;

step S2: the parameters in the vibration motor model is estimated.

After modelling the model for parameters of the vibration motor in step S1, the following expression can be obtained:

an expression of the prediction current icp[n] is:

$${i}_{c \cdot p} [ n ] = \frac{1}{{R}_{eb}} ( {v}_{c \cdot m} [ n ] - φ ( {x}_{d} [ n ] ) {u}_{d} [ n ] ) , \qquad ( 1 )$$

where, R_{eb} is a resistance of a voice coil of the motor; ϕ(x_{d}[n]) is an electromagnetic force coefficient which is a function of mechanical displacement of an oscillator x_{d}[n]; u_{d}[n] is a mechanical velocity of the oscillator, i.e., a product of an electromagnetic force and the velocity of the oscillator, V_{c·m}[n] is a back electromotive force brought to the electric circuit by the mechanical motion.

classical second-order models are modeled for both the displacement x_{d}[n] and the velocity u_{d}[n], and the expressions are as follows:

x_{d}[n]=σₓf_{c·p}[n−1]−a₁x_{d}[n−1]−a₂x_{d}[n−2] (2);

u_{d}[n]=σᵤf_{c·p}[n]−σᵤf_{c·p}[n−2]−a₁u_{d}[n−1]−a₂u_{d}[n−2] (3),

where, σₓ, σᵤ and a1/a2 are parameters of the second-order model, and f_{c·p}[n] is the electromagnetic force.

The expression of the electromagnetic force f_{c·p}[n] is:

f_{c·p}[n]=ϕ(x_{d}[n])i_{c·m}[n]−k₁(x_{d}[n])x_{d}[n] (4),

where, k₁ is a nonlinear portion of a stiffness coefficient k; in the case of linear parameters, the nonlinear term of the stiffness coefficient is 0, k₁(x_{d}[n])≈0.

As seen from the formula (2) and formula (3), although a mutual calculation relationship exists between the displacement x_{d}[n] and the electromagnetic force f_{c·p}[n], the displacement x_{d}[n] of this moment n is calculated from the electromagnetic force f_{c·p}[n−1] of the previous moment [n−1] in the formula (2), and in the formula (3), from the displacement x_{d}[n] to the electromagnetic force f_{c·p}[n], there are no memory.

In the case of barely considering the linear parameters, the above formulas can be simplified as follows:

1. the electromagnetic force coefficient ϕ(x_{d}[n]) is a constant, that is, ϕ(x_{d}[n])≈ϕ₀, and ϕ(x_{d}[n])=ϕ₀ can be obtained;

2. the nonlinear term of the stiffness coefficient is 0, that is, k₁(x_{d}[n])≈0, and k₁(x_{d}[n])=0 can be obtained;

3. there is no need to calculate the displacement x_{d}[n], that is, there is no need to perform an adaptive iteration calculation to σₓ in formula (2).

Therefore, an expression of an error function is:

$${ɛ}_{oei} [ n ] = {i}_{c \cdot m} [ n ] - {i}_{c \cdot p} [ n ] = {i}_{c \cdot m} [ n ] - \frac{1}{{R}_{eb}} ( {v}_{c \cdot m} [ n ] - {φ}_{0} ( {σ}_{u} {φ}_{0} ( {i}_{c \cdot m} [ n ] - {i}_{c \cdot m} [ n - 2 ] ) - {a}_{1} {u}_{d} [ n - 1 ] - {a}_{2} {u}_{d} [ n - 2 ] ) ) . \qquad ( 5 )$$

As to the step S2, wherein the parameters in the vibrating motor model are estimated, in the present disclosure, a classical LMS algorithm (Least mean square) is used to estimate each parameter in the formula (5), a partial derivative of each parameter is used as an update amount, and the parameter iteration is performed point by point.

Details are as follows:

resistance of the motor R_{eb},

$${R}_{eb} [ n + 1 ] = {R}_{eb} [ n ] - {μ}_{{R}_{eb}} {ɛ}_{oei} [ n ] \frac{{i}_{c \cdot p} [ n ]}{{R}_{eb} [ n ]} ; \qquad ( 6 )$$

IIR filter feedback coefficient aₖ,

$${a}_{k} [ n + 1 ] = {a}_{k} [ n ] - {μ}_{{a}_{k}} {ɛ}_{oei} [ n ] \frac{{φ}_{0} [ n ]}{{R}_{eb} [ n ]} {α}_{k} [ n ] ; \qquad ( 7 )$$

where, αₖ[n]−u_{d}[n−k]−a₁[n]αₖ[n−1]−a₂[n]αₖ[n−2] (8);

IIR filter forward coefficient σᵤ,

$${σ}_{u} [ n + 1 ] = {σ}_{u} [ n ] - {μ}_{{σ}_{u}} {ɛ}_{oei} [ n ] \frac{{φ}_{0} [ n ]}{{R}_{eb} [ n ]} {β}_{{σ}_{u}} [ n ] ; \qquad ( 9 )$$

where, β_{σ}_{ᵤ}[n]=f_{c·p}[n]−f_{c·p}[n−2]−a₁[n]β_{σ}_{ᵤ}[n−1]−a₂[n]β_{σ}_{ᵤ}[n−2] (10);

electromagnetic force coefficient ϕ₀,

$${φ}_{0} [ n + 1 ] = {φ}_{0} [ n ] - {μ}_{{φ}_{0}} {ɛ}_{oei} [ n ] ( \frac{1}{{R}_{eb} [ n ]} {u}_{d} [ n ] + \frac{{φ}_{0} [ n ]}{{R}_{eb} [ n ]} {\partial }_{φ u} [ n ] ) ; \qquad ( 11 )$$

where, ∂_{ϕu}[n]=σᵤ(i_{c·m}[n]−i_{c·m}[n−2])−a₁[n]∂_{ϕu}[n−1]−a₂[n]∂_{ϕu}[n−2] (12).

Furthermore, in order to make the LMS iteration robuster, the sample-by-sample LMS calculation can be replaced by a frame-by-frame LMS calculation.

Compared with the related art, the present disclosure provides a system and a method for controlling motor parameters, wherein the system includes a feedforward processing module performing a linear processing on a control signal according to parameters; a control object module comprising a DAC digital to analog converter, an amplifying circuit and an ADC analog to digital converter. Wherein a control signal processed by the feedforward processing module passes through the DAC digital to analog converter, and is amplified by the amplifier circuit, and then the control signal passes through the ADC analog to digital converter to obtain a voltage vcm[n] and a current icm[n] across the motor. A system identification module comprises a LMS adaptive filter, wherein a Least mean square filtering is performed on an error signal err[n] between a measurement current icm[n] and a prediction current icp[n] in the LMS adaptive filter, results of iteration are fed back to the feedforward processing module, and feedback results are applied to the next data acquisitions and parameters calculations. The system for controlling motor parameters provided by the present disclosure can solve common difficulties in actual measurement operation, can simplify the steps, facilitate the measurement and ensure the accuracy of the measurement.

The above are only the embodiments of the present disclosure, but not limit to the patent scope of the present disclosure, and equivalent structures or equivalent process transformations made by utilizing the present disclosure and the contents of the drawings, or directly or indirectly applied to other related technical fields, are all included in the scope of the patent protection of the present disclosure.

What is claimed is:

1. A system for controlling motor parameters, comprising:
a feedforward processing module which performs a linear processing on a control signal according to parameters;
a control object module, comprising a DAC digital to analog converter, an amplifying circuit and an ADC analog to digital converter, wherein a control signal processed by the feedforward processing module passes through the DAC digital to analog converter, and then is amplified by the amplifier circuit, and then passes through the ADC analog to digital converter to obtain a voltage vcm[n] and a current icm[n] across the motor;
a system identification module comprising an LMS adaptive filter, wherein a Least mean square filtering is performed on an error signal err[n] between a measurement current icm[n] and a prediction current icp[n] in the LMS adaptive filter, results of iteration are fed back to the feedforward processing module, and the feedback results are applied to the next data acquisitions and parameters calculations.

2. A method for controlling motor parameters, using the system of claim 1, comprising the following steps:
step S1: modelling a model for parameters of a vibrating motor;
step S2: estimating the parameters in the vibrating motor model.

3. The method according to claim 2, wherein an expression of the prediction current icp[n] is:
$${i}_{c \cdot p} [ n ] = \frac{1}{{R}_{eb}} ( {v}_{c \cdot m} [ n ] - φ ( {x}_{d} [ n ] ) {u}_{d} [ n ] ) ; \qquad ( 1 )$$
where, R_{eb} is a resistance of a voice coil a motor, ϕ(x_{d}[n]) is an electromagnetic force coefficient which is a function of mechanical displacement of an oscillator x_{d}[n], u_{d}[n] is a mechanical velocity of the oscillator, that is, a product of an electromagnetic force and the velocity of the oscillator, V_{c-m}[n] is a back electromotive force brought to an electric circuit by a mechanical motion.

4. The method according to claim 3, wherein in the case of linear parameters, ϕ(x_{d}[n]) is a constant, that is ϕ(x_{d}[n])≈ϕ₀.

5. The method according to claim 4, wherein a classical second-order models are modeled for both the displacement and the velocity, the expressions are as follows:
x_{d}[n]=σₓf_{c·p}[n−1]−a₁x_{d}[n−1]−a₂x_{d}[n−2] (2);
u_{d}[n]=σᵤf_{c·p}[n]−σᵤf_{c·p}[n−2]−a₁u_{d}[n−1]−a₂u_{d}[n−2] (3);
where, σₓ, σᵤ and a1/a2 are parameters of the second-order model, f_{c·p}[n] is the electromagnetic force.

6. The method according to claim 5, wherein an expression of the electromagnetic force f_{c·p}[n] is:
f_{c·p}[n]=ϕ(x_{d}[n])i_{c·m}[n]−k₁(x_{d}[n])x_{d}[n] (4);
where, k₁ is a nonlinear portion of a stiffness coefficient k; in the case of the linear parameters, the nonlinear term of the stiffness coefficient is 0, k₁(x_{d}[n])≈0.

7. The method according to claim 6, wherein an expression of an error function of an error signal err[n] is:
$${ɛ}_{oei} [ n ] = {i}_{c \cdot m} [ n ] - {i}_{c \cdot p} [ n ] = {i}_{c \cdot m} [ n ] - \frac{1}{{R}_{eb}} ( {v}_{c \cdot m} [ n ] - {φ}_{0} ( {σ}_{u} {φ}_{0} ( {i}_{c \cdot m} [ n ] - {i}_{c \cdot m} [ n - 2 ] ) - {a}_{1} {u}_{d} [ n - 1 ] - {a}_{2} {u}_{d} [ n - 2 ] ) ) . \qquad ( 5 )$$

8. The method according to claim 7, wherein a Least mean square is used in step S2 to estimate each parameter in the formula (5); a partial derivative of each parameter is used as an update amount, and a parameter iteration is performed point by point.

9. The method according to claim 8, wherein an iterative result of the motor resistance R_{eb} is:
$${R}_{eb} [ n + 1 ] = {R}_{eb} [ n ] - {μ}_{{R}_{eb}} {ɛ}_{oei} [ n ] \frac{{i}_{c \cdot p} [ n ]}{{R}_{eb} [ n ]} . \qquad ( 6 )$$

10. The method according to claim 8, wherein an iterative result of a filter feedback coefficient aₖ is:
$${a}_{k} [ n + 1 ] = {a}_{k} [ n ] - {μ}_{{a}_{k}} {ɛ}_{oei} [ n ] \frac{{φ}_{0} [ n ]}{{R}_{eb} [ n ]} {α}_{k} [ n ] ; \qquad ( 7 )$$
where, αₖ[n]=−u_{d}[n−k]−a₁[n]αₖ[n−1]−a₂[n]αₖ[n−2] (8);
an iterative result of an IIR filter feedforward coefficient σᵤ is:
$${σ}_{u} [ n + 1 ] = {σ}_{u} [ n ] - {μ}_{{σ}_{u}} {ɛ}_{oei} [ n ] \frac{{φ}_{0} [ n ]}{{R}_{eb} [ n ]} {β}_{{σ}_{u}} [ n ] . \qquad ( 9 )$$

11. The method according to claim 8, wherein an iterative result of the electromagnetic force coefficient ϕ₀ is:
$${φ}_{0} [ n + 1 ] = {φ}_{0} [ n ] - {μ}_{{φ}_{0}} {ɛ}_{oei} [ n ] ( \frac{1}{{R}_{eb} [ n ]} {u}_{d} [ n ] + \frac{{φ}_{0} [ n ]}{{R}_{eb} [ n ]} {\partial }_{φ u} [ n ] ) ; \qquad ( 11 )$$
where, ∂_{ϕu}[n]=σᵤ(i_{c·m}[n]−i_{c·m}[n−2])−a₁[n]∂_{ϕu}[n−1]−a₂[n]∂_{ϕu}[n−2] (12).
